(19) United States
(12) Patent Application Publication
(10) Pub. No.: US 2004/0031969 A1
(43) Pub. Date: Feb. 19, 2004

(54) Overvoltage protection

(75) Inventors: Jeremy Paul Smith, Wellingborough (GB); Stephen Wilton Byatt, Bromham (GB)

Correspondence Address: Howard J. Klein, KLEIN, O'NEILL & SINGH, LLP, Suite 510, 2 Park Plaza, Irvine, CA, 92614, US

(73) Assignee: Bourns Limtited, Bedford (GB)

(21) Appl. No.: 10/609,045

(22) Filed: Jun. 27, 2003

(30) Foreign Application Priority Data
Jun. 29, 2002 (GB) 0215089.4

(51) Int. Cl. H01L 29/74; H01L 31/111

(52) U.S. Cl. 257/173

(57) ABSTRACT

A semiconductor component is suitable for limiting transient voltages on the supply lines of a system having at least three supply lines, one of the supply lines being a current sink. The semiconductor comprises: at least three input means for connection to respective ones of the supply lines; and for each input means, a respective overvoltage-triggered semiconductor protection unit. Each protection unit comprises a multi-junction diode which has a threshold voltage at which it changes from a high-impedance state to a low-impedance state and a respective further diode connected in shunt with it and in the opposite sense to it. Each multi-junction diode is connected in the same sense between a respective input means and a common terminal; and each protection unit is adapted to use a lateral turn on current. A shielding diffusion is provided between adjacent protection units for blocking lateral current flow between the adjacent protection units.

### BACKGROUND OF THE INVENTION

1. Field of the Invention

The present invention relates to an overvoltage protection device.

2. Description of the Prior Art

Digital data links and the supporting circuitry often operate with signal levels less than 50V. These circuits must be protected from electrical interference that can induce much higher voltages into the signal lines which may then cause damage to the circuits. These overvoltages can arise from induced currents from power lines and from lightening discharges. The induced currents can have rise times ranging from less than a microsecond for lightening discharges to many milliseconds for induced mains currents.

There are a wide range of semiconductor devices which are designed to provide protection and many of these are based on a four layer PNPN structure which switches quickly from a blocking state to a high conduction state when the voltage cross the device exceeds a predetermined threshold or breakover voltage. Once the surge current has decayed, the PNPN device reverts back to its non-conducting state.

### BRIEF SUMMARY OF THE INVENTION

The present invention seeks to provide an improved semiconductor component.

Accordingly, the present invention provides a semiconductor component suitable for limiting transient voltages on the supply lines of a system having at least three supply lines, one of the supply lines being a current sink, the semiconductor comprising: at least three input means for connection to respective ones of the supply lines; and for each input means, a respective overvoltage-triggered semiconductor protection unit; wherein: each protection unit comprises a multi-junction diode which has a threshold voltage at which it changes from a high-impedance state to a low-impedance state and a respective further diode connected in shunt with the multi-junction diode and in the opposite sense to the multi-junction diode; each multi-junction diode is connected in the same sense between a respective input means and a common terminal; and each protection unit is adapted to use a lateral turn on current.

In a preferred embodiment of the invention a shielding diffusion is provided between adjacent protection units for blocking lateral current flow between said adjacent protection units.

Preferably, said shielding diffusion does not extend around the whole periphery of each protection unit.

Preferably, said shielding diffusion extends at least partway into the semiconductor component.

Preferably, said shielding diffusion extends the full depth of the semiconductor component.

In a further preferred embodiment the component comprises a substrate having an upper surface and a lower surface wherein: said common terminal is formed on said lower surface; the input means of each said protection unit is formed on said upper surface; and said shielding diffusion extends at least partway into said substrate from at least one of said surfaces.

Preferably, each of the further diodes has a single PN junction.

Advantageously, at least one, but not all, of the further diodes is a multi-junction diode and each of the other further diodes has a single PN junction.

In one embodiment each of the further diodes is a multi-junction diode.

### BRIEF DESCRIPTION OF THE DRAWINGS

The present invention is further described hereinafter, by way of example, with reference to the accompanying drawings, in which:

FIG. 1 is a sectional view of a first form of conventional bidirectional semiconductor component for limiting transient voltages, suitable for protecting digital circuitry;

FIG. 2 is a diagrammatic representation showing the use of three devices of FIG. 1 arranged to protect a digital circuit;

FIG. 3 is a sectional perspective view of a preferred form of semiconductor arrangement of three unidirectional components in a single integrated circuit; and

FIG. 4 is a view similar to that of FIG. 3 of a further preferred form of semiconductor according to the present invention.

### DETAILED DESCRIPTION OF THE DRAWINGS

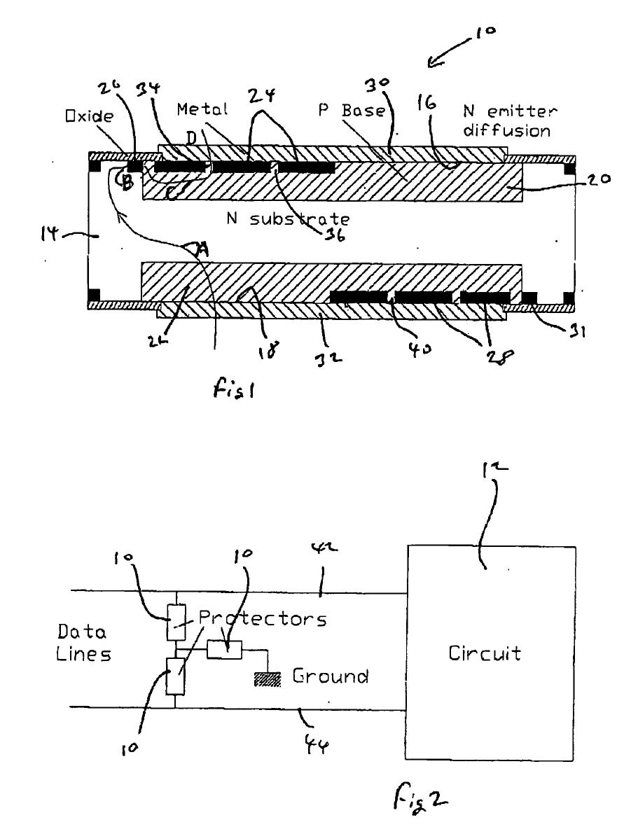

Referring firstly to FIG. 1, this shows a conventional structure of an overvoltage-triggered protection unit in the form of a bidirectional PNPN device 10 for protecting digital circuitry. Three such devices 10 are shown in FIG. 2 in an arrangement suitable for protecting a digital circuit 12.

The device of FIG. 1 is fabricated on an N type substrate 14. The substrate has upper and lower surfaces into which two P type base regions 20, 22 are diffused. Heavily doped N type emitter regions 24, 28 and breakdown regions 26, 31 are diffused into the upper and lower surfaces and electrical connection to the device 10 is made through input means in the form of upper and lower metallisations 30, 32.

The voltage at which the device 10 switches into breakdown is defined by the emitter-base junction between the base 20, 22 and the adjacent emitter breakdown region 26, 30. The breakdown voltage can be varied by varying the doping concentrations in the junction region, enabling breakdown voltages in the range 5 to 50 volts to be achieved.

The base regions 20, 22 penetrate through the associated emitter region 24, 28 by way of emitter breakdown shorting dots 34, 36 and 38, 40.

The current path A through the device 10 prior to breakdown is via the forward biassed PN junction between the base region 22 and the substrate 14, between the substrate 14 and the breakdown region 26 at B, through the base region 20 under the emitter region 24 at C and finally out of the emitter shorting dot 34. When the voltage drop along the emitter region at C is enough to forward bias the emitter junction, the device switches into its ON state.

FIG. 2 shows three such devices 10 arranged in a star formation to provide protection to two data lines 42, 44 connected to the circuit 12. As can be seen, in practice protection is required between both data lines 42, 44 and ground and therefore three such devices 10 would be required to provide full protection for the circuit 12.

Rather than having three separate devices 10 to provide protection, it is often more convenient to use a single semiconductor component. It is possible to assemble three individual devices in one package but it is much simpler and cheaper to have a single integrated circuit that performs the function of three individual protectors 10.

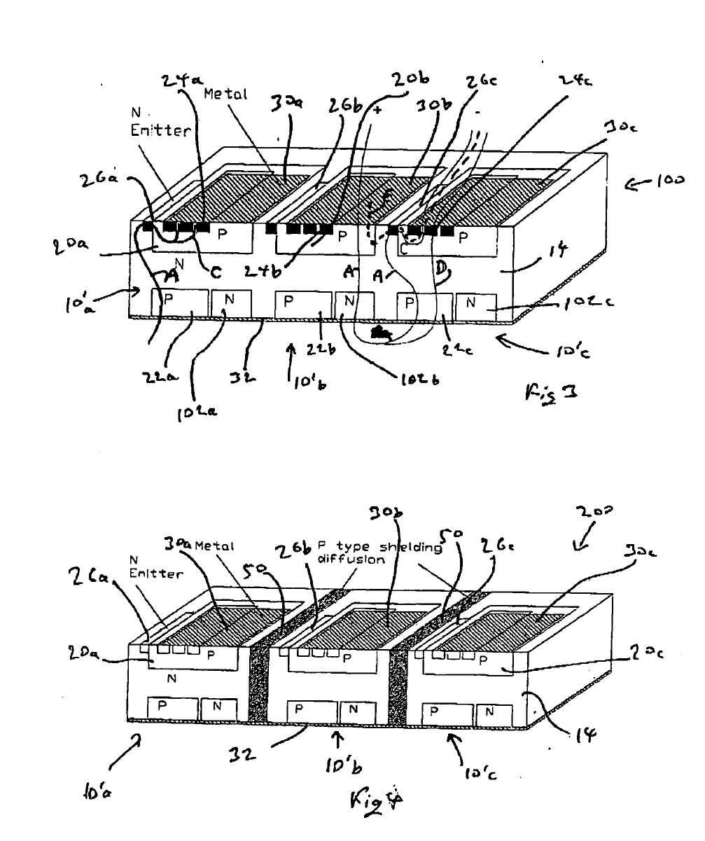

FIG. 3 shows a semiconductor component 100 which incorporates three overvoltage-triggered protection units which are similar to those shown in FIG. 1 but are unidirectional. Like parts with FIG. 1 are given like reference numbers.

In the arrangement of FIG. 3 each overvoltage-triggered protection unit or device comprises a multi-junction diode and an anti-parallel diode. The anti-parallel diode is a PN diode formed in each device 10′ between the P type base region 20 and a further N type diffusion region 102 formed in the N type substrate 14 at the lower surface of the semiconductor chip 100.

The data lines 42, 44 and ground are connected to the metallisations 30a, 30c and 30b respectively. The metallisation 32 on the lower surface of the semiconductor chip has no external connections and serves to interconnect the devices 10′.

If we assume that ground is positive relative to the data lines 42, 44 the pre-breakdown current follows the same path as shown in FIG. 1, the path being labelled A in FIG. 3. Initial triggering then occurs through the PN diode formed by the P type base 20b and the N type diffusion 102b. The current passes through the metallisation 32c and then through the anode 22c, emitter breakdown region 26c, the P type base region 20c and the shorting dot 34c. Once enough current flows to switch the PNPN section of the device the current then takes the route D which is directly through the N substrate 14, the P type base region 20c and the emitter region 24c.

The devices 10′a, 10′b and 10′c all operate in a similar manner to provide overvoltage protection in all pluralities.

The type of device illustrated in FIG. 3 provides efficient protection for power line and lightening surges with rise times of several microseconds. However, under faster current rise time conditions, it has been found with this type of device construction that the surge capability is degraded. For example, where one might expect a surge capability of 100A the actual surge capability provided under fast current rise time conditions can be as low as 50A. This loss of surge capability arises because the fast rise in voltage across the PN diode formed between the P type base region 20 and the N type diffusion 102 causes a voltage overshoot, resulting in tens of volts being dropped across the diode section. This gives rise to charge carriers building up in the body of the semiconductor and causes the triggering current for the PNPN section to flow in undesirable paths.

A typical unwanted triggering path is shown in dotted lines E in FIG. 3 where the current passes through the metallisation 30b, the P type base region 20b, the emitter breakdown region 26c, through the P base region 20c under the emitter region and out through the shorting dot 34. With tens of volts dropped vertically across the PN diode during the diode rise time, the triggering current takes the path of least resistance and in this example, the current flows laterally and does not pass through the N type diffusion 102b and the P type base region 22c of the adjacent device 10′c. Since the lateral diode formed by the P type base region 20b and the emitter breakdown region 26c has a lower current capability than that of the diode formed between the P base region 20b and the N type diffusion 102b, the surge rating of the component will be reduced. Intermediate triggering current paths can be formed depending on the current rise time and this does give unpredictable surge capability to the semiconductor component 100. The surge capability of the component is also reduced for a given area of emitter 24.

The undesirable lateral current flows can be reduced in the component 100 by increasing the separation between the devices 10′. However, this is undesirable since it increases the size of the component and thus its cost.

Referring now to FIG. 4, this shows a further preferred form of semiconductor component 200 according to the present invention. The component of FIG. 4 is similar to that of FIG. 3 and like parts have like reference numbers. The device of FIG. 3 has three overvoltage-triggered protection units or devices 10′ constructed in a similar manner to those of FIG. 3. However, the component 200 has a respective P shielding diffusion formed between adjacent pairs of devices 10′. These completely eliminate the potential unwanted triggering current paths and as a result reduce the degradation of surge capability during fast current rise time conditions.

Since the shielding diffusions 50 are only required to prevent lateral current flow under fast surge condition there is no need to surround each device 10′ in a “bucket” of P diffusion, as is the case in a conventional isolation, thus saving chip area.

The preferred form of the invention provides a low voltage semiconductor device (less than 50v) for protecting digital circuitry from transient voltages, the components using a lateral switching mechanism. The component makes use of lateral turn on whilst preventing the surge degradation which can occur as a result of parasitic current paths.

The isolation or shielding diffusion 50 of the component of FIG. 4 is a not a full isolation wall and is not designed to support significant voltage drops. It is present between adjacent devices 10′ and is designed only to block the parasitic lateral current flows which would otherwise degrade the surge capability of the component. The shielding diffusions only need to be deep enough to impede parasitic current flow sufficiently to ensure that the devices switch on properly. In FIG. 4 the shielding diffuisions 50 are shown extending the full depth of the semiconductor block. However, each shielding diffusion 50 may comprise one diffusion portion which extends into the semiconductor block from either the upper or lower surface. In a further embodiment each shielding diffusion 50 may comprise two diffusions which extend into the semiconductor block from the upper and lower surfaces respectively but do not meet in the body of the semiconductor block. In this particular case this allows shorter diffusion times and saves silicon area.

The advantage of using the illustrated diffusions 50 over providing a full isolation for each device 10′ is a reduction in the silicon area required to achieve the same surge current rating as can be achieved with the conventional component of FIG. 3. Thus, a larger surge rating may be achieved in the same area of silicon when compared to a fully isolated device.

The surge capability of the component is provided by the vertical currents.

In one embodiment each of the further anti-parallel diodes has a single PN junction.

In another embodiment at least one, but not all, of the further diodes is a multi-junction diode and each of the other further diodes has a single PN junction.

In another embodiment each of the further diodes is a multi-junction diode.

1. A semiconductor component suitable for limiting transient voltages on the supply lines of a system having at least three supply lines, one of the supply lines being a current sink, the semiconductor comprising:
at least three input means for connection to respective ones of the supply lines;
and for each input means, a respective overvoltage-triggered semiconductor protection unit;
wherein:
each protection unit comprises a multi-junction diode which has a threshold voltage at which it changes from a high-impedance state to a low-impedance state and a respective further diode connected in shunt with the multi-junction diode and in the opposite sense to the multi-junction diode;
each multi-junction diode is connected in the same sense between a respective input means and a common terminal;
and each protection unit is adapted to use a lateral turn on current.

2. A semiconductor component as claimed in claim 1 wherein a shielding diffusion is provided between adjacent protection units for blocking lateral current flow between said adjacent protection units.

3. A semiconductor component as claimed in claim 2 wherein said shielding diffusion does not extend around the whole periphery of each protection unit.

4. A semiconductor component as claimed in claim 2 wherein said shielding diffusion extends at least partway into the semiconductor component.

5. A semiconductor component as claimed in claim 2 wherein said shielding diffusion extends the full depth of the semiconductor component.

6. A semiconductor component as claimed in claim 2 comprising a substrate having an upper surface and a lower surface wherein:
said common terminal is formed on said lower surface;
the input means of each said protection unit is formed on said upper surface;
and said shielding diffusion extends at least partway into said substrate from at least one of said surfaces.

7. A semiconductor component as claimed in claim 2 wherein each of the further diodes has a single PN junction.

8. A semiconductor component as claimed in claim 2 wherein at least one, but not all, of the further diodes is a multi-junction diode and each of the other further diodes has a single PN junction.

9. A semiconductor component as claimed in claim 2 wherein each of the further diodes is a multi-junction diode.
